(19) United States
(12) Patent Application Publication
(10) Pub. No.: US 2016/0196968 A1
(43) Pub. Date: Jul. 7, 2016

(54) PATTERNING METHOD

(71) Applicant: MACRONIX International Co., Ltd., Hsinchu (TW)

(72) Inventors: Chia-Hua Lin, Hsinchu (TW); Tien-Chu Yang, Hsinchu (TW); Chih-Hao Huang, Hsinchu (TW)

(21) Appl. No.: 14/590,526

(22) Filed: Jan. 6, 2015

(51) Int. Cl. H01L 21/027; G03F 7/32; G03F 7/38; G03F 7/20

(52) U.S. Cl. CPC H01L 21/0276; G03F 7/20; G03F 7/32; G03F 7/38

(57) ABSTRACT

A patterning method is provided. A photoresist layer is formed on a target layer. An etching resistance layer is formed on the photoresist layer. The photoresist layer is exposed to light and therefore a photo acid is generated in first regions of the photoresist layer. The photoresist layer is developed to remove second regions of the photoresist layer. It is noted that the etching resistance layer is non-photosensitive but reactive to the generated photo acid.

### BACKGROUND OF THE INVENTION

1. Field of Invention

The present invention relates to a semiconductor process, and more particularly to a patterning method in a photolithography stage.

2. Description of Related Art

As the level of integration of integrated circuits is getting increased, the demand for increasing the feature density or reducing the pitch size becomes the mainstream in the semiconductor industry, and the key technology is in photolithography. In the photolithography process, a photoresist layer is coated on a wafer. The photoresist layer is exposed to light and therefore a portion thereof is polymerized. The photoresist layer is developed to dissolve the non-polymerized portion thereof. The resulting photoresist layer can be used as an etching mask for the subsequent etching process.

However, the photoresist loss is often observed at post exposure baking (PEB), thereby resulting in an undesired thinner photoresist layer. In such case, the etching resistance property of the photoresist layer is accordingly reduced. On the other hand, the traditional lithography has its limitation on printing small geometry beyond the resolution of photolithography. Therefore, how to maintain the effective photoresist thickness as well as reduce the device dimension has been drawn high attention in the industry.

### SUMMARY OF THE INVENTION

The present invention provides a patterning method, in which an etching resistance layer can be provided on an exposed or unexposed photoresist layer, and parts of the etching resistance layer are harden during a baking step to form protection layers respectively on photoresist patterns. By such method, the effective photoresist thickness can be maintained, and the device dimension can be reduced.

The present invention provides a patterning method. A photoresist layer is formed on a target layer. An etching resistance layer is formed on the photoresist layer. The photoresist layer is exposed and therefore a photo acid is generated in first regions of the photoresist layer. The photoresist layer is developed to remove second regions of the photoresist layer. Besides, the etching resistance layer is non-photosensitive but reactive to the generated photo acid.

According to an embodiment of the present invention, the photo acid includes a hydrogen ion.

According to an embodiment of the present invention, the etching resistance layer includes a silicon-containing material layer.

According to an embodiment of the present invention, the patterning method further includes baking the photoresist layer after the exposing step and before the developing step, so that the generated photo acid in the first regions of the photoresist layer hardens parts of the etching resistance layer directly on the first regions.

According to an embodiment of the present invention, the baking step is a post exposure baking (PEB) step performed at about 60 to 250° C. for about 10 to 600 seconds.

According to an embodiment of the present invention, unhardened parts of the etching resistance layer is simultaneously removed during the developing step.

According to an embodiment of the present invention, the first regions are exposed regions, and the second regions are unexposed regions.

According to an embodiment of the present invention, the photoresist layer includes a positive photoresist material.

According to an embodiment of the present invention, a developer used in the developing step includes a negative tone developer.

According to an embodiment of the present invention, the patterning method further includes forming a bottom anti-reflection coating (BARC) layer on the target layer before the step of forming the photoresist layer.

The present invention further provides a patterning method. A photoresist layer is formed on a target layer. The photoresist layer is exposed and therefore a photo acid is generated in first regions of the photoresist layer. The photoresist layer is developed to remove second regions of the photoresist layer while remaining the first regions of the photoresist layer. An etching resistance layer is formed on the photoresist layer, wherein the etching resistance layer fills in gaps between the first regions of the photoresist layer. Besides, the etching resistance layer is non-photosensitive but reactive to the generated photo acid.

According to an embodiment of the present invention, the photo acid includes a hydrogen ion.

According to an embodiment of the present invention, the etching resistance layer includes a silicon-containing material layer.

According to an embodiment of the present invention, the patterning method further includes baking the photoresist layer after the step of forming the etching resistance layer, so that the generated photo acid in the first regions of the photoresist layer hardens parts of the etching resistance layer contacting the first regions.

According to an embodiment of the present invention, the baking step is performed at about 60 to 250° C. for about 10 to 600 seconds.

According to an embodiment of the present invention, the patterning method further includes removing unhardened parts of the etching resistance layer with a removing agent, wherein the removing agent includes a negative tone developer.

According to an embodiment of the present invention, the first regions are exposed regions, and the second regions are unexposed regions.

According to an embodiment of the present invention, the photoresist layer includes a positive photoresist material.

According to an embodiment of the present invention, a developer used in the developing step includes a negative tone developer.

According to an embodiment of the present invention, the patterning method further includes forming a bottom anti-reflection coating (BARC) layer on the target layer before the step of forming the photoresist layer.

Based on the above, in the patterning method of the present invention, before or after a photoresist layer is subjected to an exposing step, an etching resistance layer can be provided on the photoresist layer. The etching resistance layer reacts with the photo acid from the underlying photoresist layer during a baking step and therefore forms a hardened part at least on top of each photoresist pattern. The hardened part serves as a protection layer for the corresponding photoresist pattern, so that the effective photoresist thickness can be maintained. In an embodiment, the hardened part is formed on top and sidewall of each photoresist pattern, and thus, the device dimension (specifically the width of holes or trenches) can be reduced.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are schematic cross-sectional views of a patterning method according to a first embodiment of the present invention.

FIG. 2A to FIG. 2F are schematic cross-sectional views of a patterning method according to a second embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

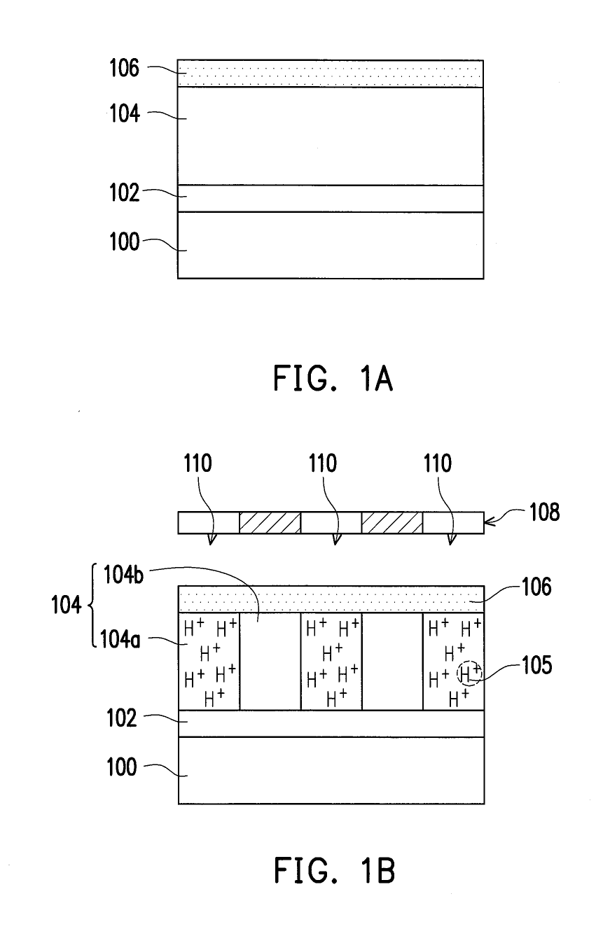

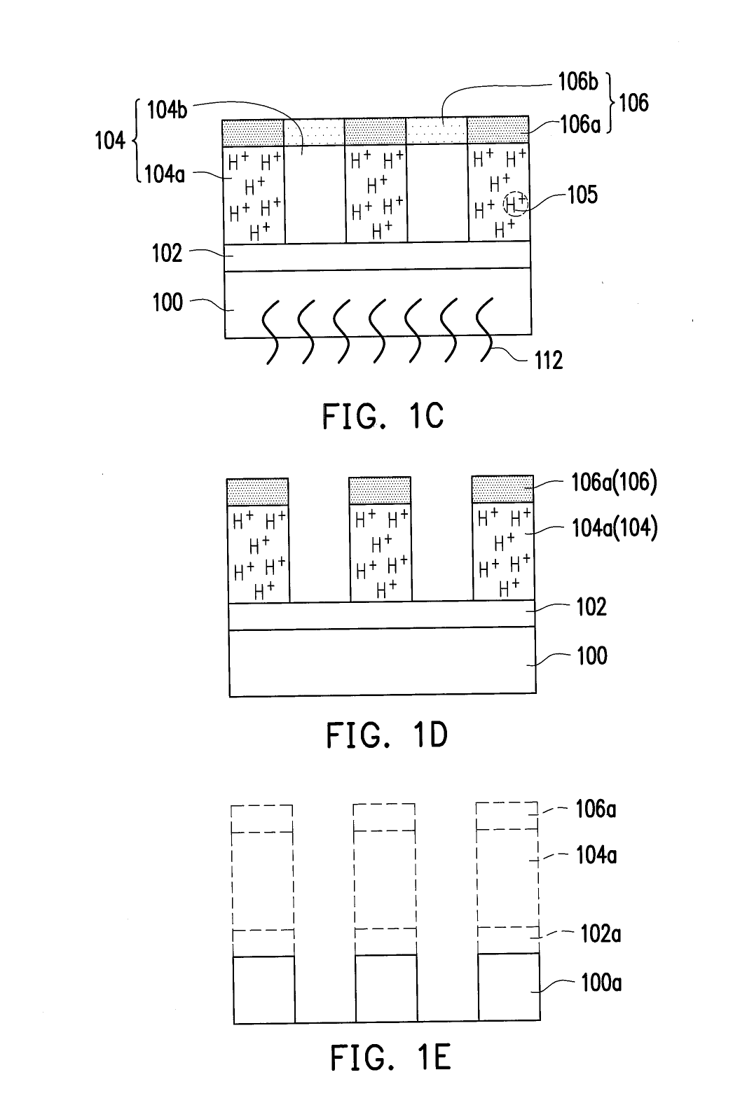

FIG. 1A to FIG. 1E are schematic cross-sectional views of a patterning method according to a first embodiment of the present invention.

Referring to FIG. 1A, an optional bottom anti-reflection coating (BARC) layer 102 and a photoresist layer 104 are sequentially formed on a target layer 100. The target layer 100 includes a conductive material, a dielectric material, a semiconductor material or a combination thereof. The BARC layer 102 is configured to reduce the light reflection from the underlying layer(s). The photoresist layer 104 includes a positive photoresist material, such as a 365 nm (I-line) photoresist, a 248 nm (KrF) photoresist, a 193 nm (ArF) photoresist, a immerion-193 nm (immersion-ArF) photoresist or any suitable photoresist. The method of forming each of the BARC layer 102 and the photoresist layer 104 includes performing a spin coating step.

In an embodiment, the photoresist layer 104 can include a photosensitive resin, a photo-acid generator and a solvent for balance. When the photoresist layer 104 is irradiated with light, characteristics of the photosensitive resin may vary, and the photo-acid generator may generate a photo acid, such as a hydrogen ion (H⁺).

Thereafter, an etching resistance layer 106 is formed on the photoresist layer 104. The etching resistance layer 106 has an etching resistance higher than that of the photoresist layer 104. In an embodiment, the etching resistance layer 106 includes a silicon-containing material layer. The method of forming the etching resistance layer 106 includes performing a spin coating step. Besides, the etching resistance layer 106 is non-photosensitive but reactive to a photo acid.

Referring to FIG. 1B, the photoresist layer 104 is exposed to light 110 through a photomask 108. During the exposing step, a photo acid 105 is generated in first regions 104a of the photoresist layer 104. The photo acid 105 includes a hydrogen ion (H⁺), for changing the polarity of the first regions 104a. In an embodiment, after the exposing step, the photoresist layer 104 has the exposed first regions 104a and the unexposed second regions 104b therein. Specifically, the first regions 104a of the photoresist layer 104 are exposed regions corresponding to the transparent regions of the photomask 108, and the second regions 104b of the same are unexposed regions corresponding to the opaque regions of the photomask 108. Since the etching resistance layer 106 is non-photosensitive, the properties of the etching resistance layer 106 substantially maintain as the original upon the exposing step.

Referring to FIG. 1C, the photoresist layer 104 is baked with heat 112, so that the generated photo acid 105 in the first regions 104a of the photoresist layer 104 hardens parts of the etching resistance layer 106 directly on the first regions 104a. Specifically, since the etching resistance layer 106 is reactive to the photo acid 105, a cross-linking reaction of the etching resistance layer 106 takes place by catalysis of the photo acid 105 which comes from the top surfaces of the exposed first regions 104. Therefore, the parts of the etching resistance layer 106 contacting the photo acid 105 of first regions 104a are transformed into hardened parts 106a. As a result, the etching resistance layer 106 has hardened parts 106a and unhardened parts 106b after the baking step. The baking step is a post exposure baking (PEB) step performed at about 60 to 250° C. for about 10 to 600 seconds.

Referring to FIG. 1D, the photoresist layer 104 is developed with a developer, so as to remove second regions 104b of the photoresist layer 104 while remaining the first regions 104a of the photoresist layer 104. Besides, the unhardened parts 106b of the etching resistance layer 106 are simultaneously removed during the developing step. The developer includes a negative tone developer (NTD). The negative tone developer can be a solvent-based developer including an organic solvent. After the developing step, the first regions 104a of the photoresist layer 104 and the hardened parts 106a of the etching resistance layer 106 are provided on the BRAC layer 102. Here, each hardened part 106a of the etching resistance layer 106 serves as a protection layer to prevent the corresponding underlying first region 104a from being damaged during the subsequent etching process.

It is noted that the conventional photoresist loss issue can be successfully resolved by forming the etching resistance layer of the invention on the photoresist layer. Specifically, the etching resistance property of a resist which uses a negative tone developer (NTD, solvent based development) is lower than that of the conventional resist which uses a positive tone developer (PTD, aqueous based development), so the photoresist loss is often observed at post exposure baking (PEB) for a NTD resist. However, in the present invention, the etching resistance layer is configured to form on the photoresist layer. In such manner, since the etching resistance layer is non-photosensitive but reactive to a photo acid, it forms a hardened part as a protection layer during a baking step on each photoresist pattern (i.e. first region 104a). Therefore, the total film thickness of the pattern is increased, so the etching resistance during the following etching process can be enhanced.

Referring to FIG. 1E, a portion of the target layer 100 is removed through an etching process by using the first regions 104a and the hardened parts 106a as a mask, so as to form a patterned target layer 100a. A portion of the BARC layer 102 is simultaneously removed to form a patterned BARC layer 102a during the patterning step of the target layer 100. Thereafter, the patterned BARC layer 102a, the first regions 104a and the hardened parts 106a are removed through another etching process. The patterning method of the present invention is thus completed.

In view of the foregoing, the patterning method of the present invention applies a positive photoresist layer and a negative tone developer in combination with use of an etching resistance layer. Since the etching resistance layer is non-photosensitive but reactive to the generated photo acid, hardened parts can be formed on respective photoresist patterns to maintain the effective photoresist thickness.

The first embodiment in which the etching resistance layer 106 is formed after the coating step and before the exposing step is provided for illustration purposes, and is not construed as limiting the present invention. For example, the etching resistance layer can be formed after the developing step so as to further reduce the device dimension, as described in the second embodiment below.

### Second Embodiment

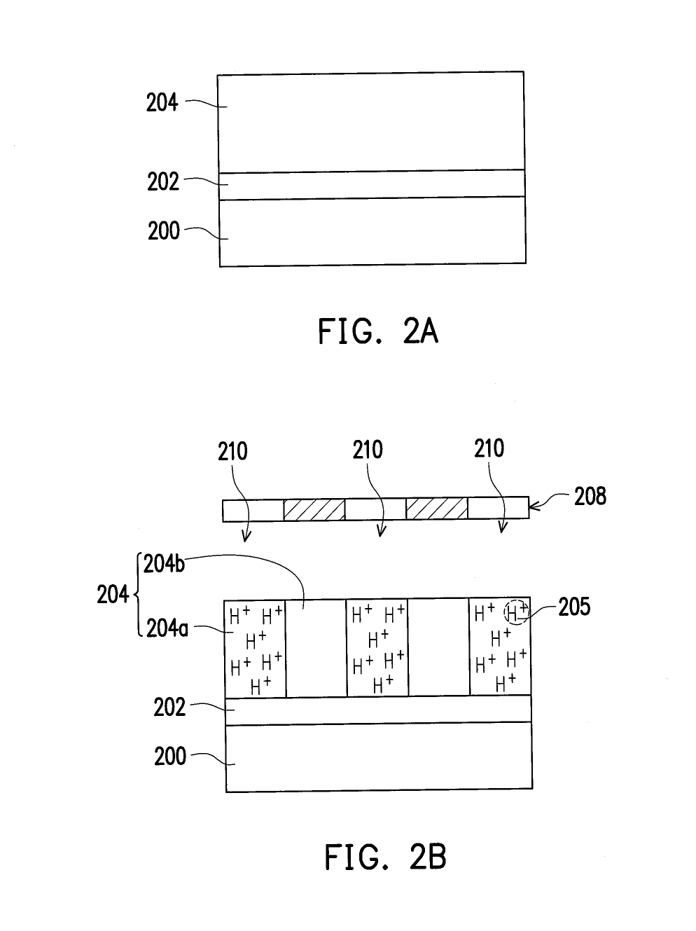

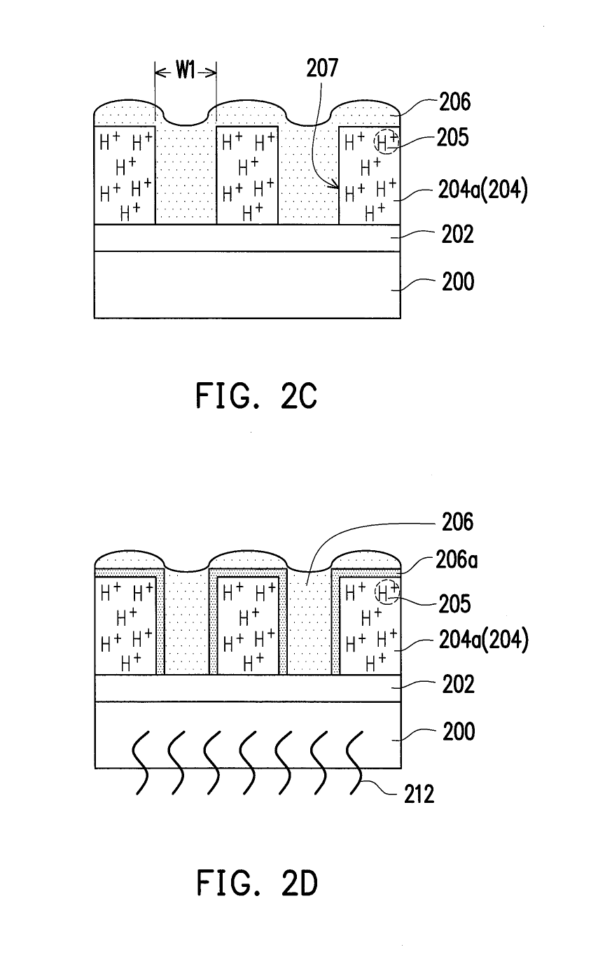

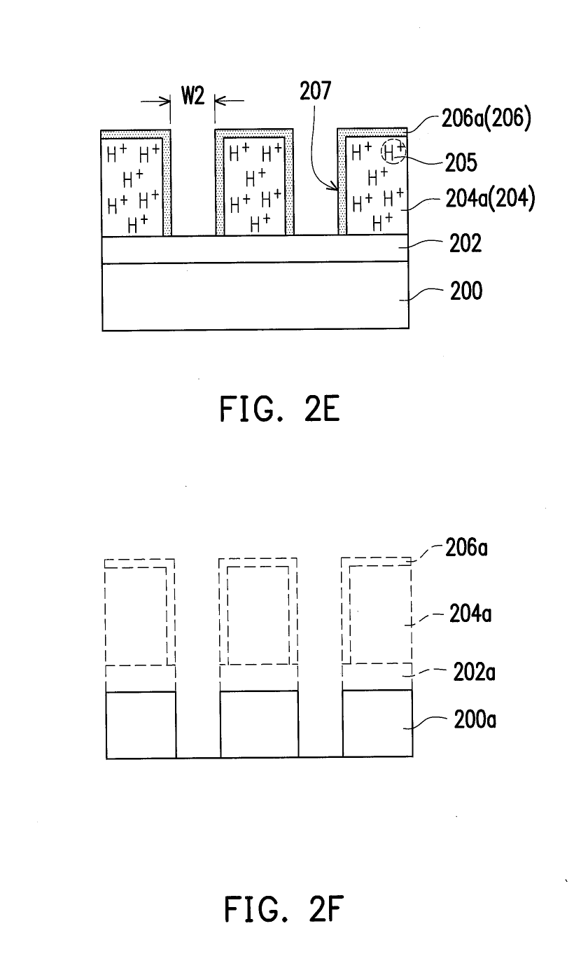

FIG. 2A to FIG. 2F are schematic cross-sectional views of a patterning method according to a second embodiment of the present invention.

Referring to FIG. 2A, an optional BARC layer 202 and a photoresist layer 204 are sequentially formed on a target layer 200. The photoresist layer 204 includes a positive photoresist material, such as a 365 nm (I-line) photoresist, a 248 nm (KrF) photoresist, a 193 nm (ArF) photoresist, a immerion-193 nm (immersion-ArF) photoresist or any suitable photoresist. The method of forming each of the BARC layer 202 and the photoresist layer 204 includes performing a spin coating step.

Referring to FIG. 2B, the photoresist layer 204 is exposed to light 210 through a photomask 208. During the exposing step, a photo acid 205 is generated in first regions 204a of the photoresist layer 204. The photo acid 205 includes a hydrogen ion (H⁺), for changing the polarity of the exposed first regions 204a. In an embodiment, after the exposing step, the photoresist layer 204 has the exposed first regions 204a and the unexposed second regions 204b therein. Thereafter, the photoresist layer 204 is subjected to a post exposure baking (PEB) step performed at about 60 to 250° C. for about 10 to 600 seconds.

Referring to FIG. 2C, the photoresist layer 204 is developed with a developer, so as to remove second regions 204b of the photoresist layer 204 while remaining the first regions 204a of the photoresist layer 204. The developer includes a negative tone developer (NTD). The negative tone developer can be a solvent-based developer including an organic solvent. After the developing step, the first regions 204a of the photoresist layer 204 are provided on the BRAC layer 202.

Continue referring to FIG. 2C, an etching resistance layer 206 is formed on the photoresist layer 204. The etching resistance layer 206 fills in gaps 207 between the first regions 204a of the photoresist layer 204. In an embodiment, the gaps 207 between the adjacent first regions 204a have a width W1 equal to the resolution of photolithography. The etching resistance layer 206 has an etching resistance higher than that of the photoresist layer 204. In an embodiment, the etching resistance layer 206 includes a silicon-containing material layer. The method of forming the etching resistance layer 206 includes performing a spin coating step. Besides, the etching resistance layer 206 is non-photosensitive but reactive to the photo acid 205.

Referring to FIG. 2D, the photoresist layer 204 is baked with heat 212, so that the generated photo acid 205 in the first regions 204a of the photoresist layer 204 hardens parts of the etching resistance layer 206 contacting the first regions 204a. Specifically, since the etching resistance layer 206 is reactive to the photo acid 205, a cross-linking reaction of the etching resistance layer 206 takes place by catalysis of the photo acid 205 which comes from the top and sidewall surfaces of the exposed first regions 204a. Therefore, the parts of the etching resistance layer 206 contacting the photo acid 205 of first regions 204a are transformed into hardened parts 206a. As a result, the top and the sidewall of each first region 204a is covered by the corresponding hardened part 206a of the etching resistance layer 206. The baking step is performed at about 60 to 250 t for about 10 to 600 seconds.

Referring to FIG. 2E, the remaining unhardened parts of the etching resistance layer 206 is removed with a removing agent. The removing agent includes a negative tone developer (NTD). The negative tone developer can be a solvent-based developer including an organic solvent. Besides, the removing agent for removing the etching resistance layer 206 can include a material the same as or different from the developer for developing the photoresist layer 204. In an embodiment, since the sidewall of each first region 204a is covered by the corresponding hardened part 206a, the width of the gaps 207 between the adjacent first regions 204a is accordingly reduced. In an embodiment, the gaps 207 between the adjacent first regions 204a have a width W2 beyond the resolution of photolithography.

Referring to FIG. 2F, a portion of the target layer 200 is removed through an etching process by using the first regions 204a and the hardened parts 206a as a mask, so as to form a patterned target layer 200a. A portion of the BARC layer 202 is simultaneously removed to form a patterned BARC layer 202a during the patterning step of the target layer 200. Thereafter, the patterned BARC layer 202a, the first regions 204a and the hardened parts 206a are removed through another etching process. The patterning method of the present invention is thus completed.

In summary, in the patterning method of the present invention, before or after a photoresist layer is subjected to an exposing step, an etching resistance layer can be provided on the photoresist layer. The etching resistance layer reacts with the photo acid from the underlying photoresist layer during a baking step and therefore forms a hardened part on each photoresist pattern (i.e. each first region of the photoresist layer). In an embodiment, the hardened part can be formed at least on top of the corresponding photoresist pattern, so that the effective photoresist thickness can be maintained. In another embodiment, the hardened part can be formed on top and sidewall of each photoresist pattern, and thus, the device dimension can be reduced. With the method of the invention, the width of holes or trenches can be successfully decreased to beyond the resolution of photolithography. The patterning method of the invention is very competitive because it can effectively shrink the pattern size and reduce the line width roughness, contact edge roughness, line pattern pinching and contact hole bridging in the semiconductor patterning using an NTD photo process.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

1. A patterning method, comprising:
forming a photoresist layer on a target layer;
forming an etching resistance layer on the photoresist layer;
exposing the photoresist layer and the etching resistance layer through a photomask and therefore generating a photo acid in first regions of the photoresist layer;
baking the photoresist layer after the exposing step, so that the generated photo acid in the first regions of the photoresist layer hardens parts of the etching resistance layer directly on the first regions; and
developing the photoresist layer after the baking step to remove second regions of the photoresist layer and unhardened parts of the etching resistance layer,
wherein the etching resistance layer is non-photosensitive but reactive to the generated photo acid.

2. The patterning method of claim 1, wherein the photo acid comprises a hydrogen ion.

3. The patterning method of claim 1, wherein the etching resistance layer comprises a silicon-containing material layer.

4. (canceled)

5. The patterning method of claim 1, wherein the baking step is a post exposure baking (PEB) step performed at about 60 to 250° C. for about 10 to 600 seconds.

6. (canceled)

7. The patterning method of claim 1, wherein the first regions are exposed regions, and the second regions are unexposed regions.

8. The patterning method of claim 1, wherein the photoresist layer comprises a positive photoresist material.

9. The patterning method of claim 1, wherein a developer used in the developing step comprises a negative tone developer.

10. The patterning method of claim 1, further comprising forming a bottom anti-reflection coating (BARC) layer on the target layer before the step of forming the photoresist layer.

11. A patterning method, comprising:
forming a photoresist layer on a target layer;
exposing the photoresist layer through a photomask and therefore generating a photo acid in first regions of the photoresist layer;
developing the photoresist layer to remove second regions of the photoresist layer while remaining the first regions of the photoresist layer; and
forming an etching resistance layer on the photoresist layer after the developing step, wherein the etching resistance layer fills in gaps between the first regions of the photoresist layer,
wherein the etching resistance layer is non-photosensitive but reactive to the generated photo acid.

12. The patterning method of claim 11, wherein the photo acid comprises a hydrogen ion.

13. The patterning method of claim 11, wherein the etching resistance layer comprises a silicon-containing material layer.

14. The patterning method of claim 11, further comprising baking the photoresist layer after the step of forming the etching resistance layer, so that the generated photo acid in the first regions of the photoresist layer hardens parts of the etching resistance layer contacting the first regions.

15. The patterning method of claim 14, wherein the baking step is performed at about 60 to 250° C. for about 10 to 600 seconds.

16. The patterning method of claim 14, further comprising removing unhardened parts of the etching resistance layer with a removing agent, wherein the removing agent comprises a negative tone developer.

17. The patterning method of claim 11, wherein the first regions are exposed regions, and the second regions are unexposed regions.

18. The patterning method of claim 11, wherein the photoresist layer comprises a positive photoresist material.

19. The patterning method of claim 11, wherein a developer used in the developing step comprises a negative tone developer.

20. The patterning method of claim 11, further comprising forming a bottom anti-reflection coating (BARC) layer on the target layer before the step of forming the photoresist layer.
